(19) United States
(12) Patent Application Publication
(10) Pub. No.: US 2013/0018607 A1
(43) Pub. Date: Jan. 17, 2013

(54) PERFORMANCE VERIFICATION APPARATUS FOR RENEWABLE ENERGY MODULE AND METHOD THEREOF

(71) Applicants: Byoung Jin Jin, Yongin-si (KR); Byoung Ho Chong, Suwon-si (KR); Sung Bae Jung, Suwon-si (KR)

(72) Inventors: Byoung Jin Jin, Yongin-si (KR); Byoung Ho Chong, Suwon-si (KR); Sung Bae Jung, Suwon-si (KR)

(21) Appl. No.: 13/193,240

(22) Filed: Jul. 28, 2011

(30) Foreign Application Priority Data
Jul. 13, 2011 (KR) 10-2011-0069429

(51) Int. Cl. G06F 19/00; G01R 21/00

(52) U.S. Cl. 702/60

(57) ABSTRACT

Provided are a performance verification system for a renewable energy module and a method thereof, and more particularly, a performance verification apparatus for a renewable energy module capable of improving measurement precision for a variable output state of the renewable energy module, such as a solar cell, and reducing an error through an electrical load and a precise measurement unit, and a method thereof. It is possible to increase reliability of real measurement data and calculate a result closest to a maximum power point by compensating for power loss caused by resistance of a cable constituting a system, internal resistance of a voltage sensor, and a measurement cable.

### CROSS-REFERENCE TO RELATED APPLICATION

This application claims priority to and the benefit of Korean Patent Application No. 10-2011-0069429, filed on Jul. 13, 2011, the disclosure of which is incorporated herein by reference in its entirety.

### BACKGROUND

1. Field of the Invention

The present invention relates to a performance verification system for a renewable energy module and a method thereof, and more particularly, to a performance verification apparatus for a renewable energy module capable of improving measurement precision for a variable output state of the renewable energy module, such as a solar cell, and reducing an error through an electrical load and a precise measurement unit, and a method thereof.

2. Discussion of Related Art

Recently, with the exhaustion of natural resources and issues of an environment and safety of thermal and nuclear power generation, use of renewable energy such as sunlight, water, geothermal heat, biological organisms and the like in place of existing fuel is fast growing. Various modules for converting such renewable energy into a desired type of energy have appeared.

Representative examples of the renewable energy module include a solar cell for converting sunlight into electric energy or an aerogenerator for generating electric energy using wind.

However, existing electric energy has a uniform output and is stable in operation even when a load is linear or non-linear. On the other hand, a renewable energy module is a power source exhibiting a non-linear characteristic according to a variable power generation environment.

Accordingly, the renewable energy module has a characteristic of a non-linear current source whose output voltage and current is not constant, but output voltage is determined according to load current. Generated power has a characteristic varying with a load.

To verify efficiency of such a renewable energy module, it is necessary to accurately detect a point at which a maximum power is always generated.

An existing performance verification apparatus for a solar cell that judges efficiency through tracking of a maximum power point using a solar cell among the renewable energy modules, as described above, may include, for example, a solar cell array 1, a current measurement device 2, a voltage divider circuit 3, a microcomputer 4, an inverter 6, and a load 5, as shown in FIG. 1.

A detailed operation of this configuration will be described. An output voltage of the solar cell 1 is measured by the microcomputer 4 via the voltage divider circuit 3, and supply current is also measured by the microcomputer 4 via the current measurement device 2. The microcomputer 4 then processes the input signal using a previously set algorithm and controls the inverter 6 to change the voltage and the current consumed by the load 5 for maximum efficiency.

However, in the verification apparatus as described above, measurement is performed without consideration of power loss caused by resistance of a cable in a process of sending the voltage and the current via the cable using the inverter 6, leading to low accuracy and reliability.

Further, since the solar cell 1 is a non-linear energy source having an instantaneously variable output, power provided by the solar cell 1 is not completely consumed when the load 5 is constant, making accurate detection of maximum efficiency with the microcomputer 4 difficult. As a result, controlling the inverter 6 is useless. When the load 5 is changed, the inverter 6 is difficult to precisely control according to the change of the load 5, and reliability of accurate maximum efficiency measurement is degraded due to power consumed by the inverter 6 itself

In addition, since there is a difference between a voltage measurement point in the voltage divider circuit 3 and a current measurement point in the current measurement device 2, a process of synchronizing between the voltage and current measurement points in the microcomputer is necessary. Accordingly, there is a difference in operation time between the inverter 6 for adjusting current and voltage values provided to the load 5 and the microcomputer 4 for controlling the inverter 6, which causes non-synchronization and low reliability.

In addition to the existing performance verification apparatus for a solar cell as described above, a power generation circuit for a solar cell for inducing a maximum output of the solar cell as shown in FIG. 2 is disclosed in Patent No. 0276791. The power generation circuit includes a solar cell array 71, a power controller 72 for rectifying an output power of the solar cell array 71, a load 73 for using the rectified power, a switch 81 connected between the solar cell array 71 and the power controller 72 for maximizing the output power of the solar cell array 71, a solar cell opening adjuster 82 for controlling the switch 81, an open voltage sensing unit 83 for measuring an open voltage of the solar cell array 71, a timer 84, and a maximum voltage setting unit 85.

Such a configuration also tracks the maximum voltage without consideration of resistance of a cable that connects the solar cell array 71 to the power controller 72 and contact resistance. Accordingly, there is a difference between power actually generated by the solar cell 71 and power available to the load, leading to low precision.

In addition, with such a configuration that measures the current-voltage characteristic according to a physical switching operation, it is impossible to realize fast measurement. The maximum voltage setting unit 85 for setting a maximum voltage based on an open voltage sensed when the switch is opened has a simple circuit configuration. However, since only a voltage is considered in maximum power measurement for maximum efficiency, there are problems of low precision, as well as low reliability due to an internal error caused by non-consideration of voltage and current measurement points and a great difference between a real maximum power of the solar cell and a maximum power tracked through a maximum voltage.

Accordingly, with such a configuration, it is difficult to anticipate high precision since only simplification of the configuration of the apparatus has been considered, while various parameters for maximum power have not been considered.

There is a need for a new performance verification apparatus for a renewable energy module for resolving the problems with the existing performance verification apparatus for maximum efficiency of the renewable energy module as described above.

### PRIOR ART DOCUMENT

Patent Document 1: Korean Patent No. 0276791

### SUMMARY OF THE INVENTION

The present invention is directed to a performance verification apparatus capable of increasing reliability of tracking of a maximum power by compensating for power loss caused by resistance of a cable in an existing apparatus for verifying a renewable energy module through maximum power tracking.

The present invention is also directed to improving measurement precision by precisely measuring voltage and current of a renewable energy module with no distortion caused by contact resistance and a measurement cable for measurement in voltage measurement and measuring operation of an electrical load and a resultant change of voltage and current with accurate synchronization.

The present invention is also directed to performing accurate estimation of a maximum power by improving a measurement point cycle by increasing consumption of current provided by a renewable energy module according to a characteristic of a renewable energy module, which is a non-linear power source.

According to an aspect of the present invention, a performance verification apparatus for a renewable energy module includes an electrical load that consumes power output from the renewable energy module through variation of internal resistance, the electrical load including a voltage sensor and a current measurement terminal; a precise measurement unit for measuring a voltage with no distortion caused by contact resistance and internal resistance of a cable for voltage measurement and measuring current flowing through the electrical load, the precise measurement unit having an input terminal connected to an input terminal of the voltage sensor of the electrical load together with an output terminal of the renewable energy module using a 4-wire method; a boost power unit for providing the electrical load with a compensation power previously set according to a loss power caused by a cable for connecting the input terminal of the voltage sensor to the output terminal of the renewable energy module; and a control unit for receiving the measured voltage and current from the precise measurement unit to perform control of the electrical load and synchronization between the measured voltage and current, and tracking a maximum power point using a Maximum Power Point Tracking (MPPT) algorithm based on the synchronized measured voltage and current of the electrical load, wherein the control unit collects an I-V sweeping result of the renewable energy module as characteristic information by adjusting the electrical load during operation of the MPPT algorithm.

In this case, the boost power unit may provide a fixed DC voltage to the electrical load to accelerate power consumption of the electrical load.

Further, the control unit may set a voltage corresponding to the maximum power point as a reference voltage, and extract a power with a maximum value among a plurality of powers generated by increasing or decreasing a voltage based on the reference voltage, as a next maximum power point.

In addition, the control unit may update the reference voltage with a voltage corresponding to the next maximum power point measured through the reference voltage, and update the reference voltage with a voltage corresponding to a maximum power point at a previous measurement point to extract the maximum power point for each measurement point.

Meanwhile, the characteristic information may contain at least one of I-V sweeping information, current-voltage characteristic information, power-voltage characteristic information, and maximum power point extraction information for each measurement point.

In addition, the performance verification apparatus may further include a waveform generation unit for providing a signal to change the resistance of the electrical load, wherein the control unit may synchronize the voltage and the current measured by the precise measurement unit according to the signal from the waveform generation unit to track a maximum power point.

According to another aspect of the present invention, a performance verification method for a renewable energy module includes a first step of receiving, by an electrical load, voltage and current from the renewable energy module, the electrical load including a voltage sensor and a current measurement terminal; a second step of providing, by a boost power unit, the electrical load with a compensation power previously set according to resistance of a cable for connecting the input terminal of the voltage sensor to an output terminal of the renewable energy module; a third step of measuring, by a precise measurement unit, a voltage with no distortion caused by contact resistance and internal resistance of a cable and measuring current flowing through the electrical load, the precise measurement unit having an input terminal connected to an input terminal of the voltage sensor of the electrical load together with an output terminal of the renewable energy module using a 4-wire method; and a fourth step of receiving, by a control unit, the measured voltage and current from the precise measurement unit to perform control of the electrical load and synchronization between the measured voltage and current, and tracking a maximum power point using a Maximum Power Point Tracking (MPPT) algorithm based on the synchronized measured voltage and current, wherein the control unit collects an I-V sweeping result of the renewable energy module as characteristic information by adjusting the electrical load during operation of the MPPT algorithm.

In this case, the performance verification method may further include a fifth step of setting, by the control unit, a voltage corresponding to the maximum power point as a reference voltage, and extracting a power with a maximum value among a plurality of powers generated by increasing or decreasing a voltage based on the reference voltage, as a next maximum power point.

Further, the fifth step may include updating, by the control unit, the reference voltage with a voltage corresponding to the next maximum power point measured through the reference voltage, and updating the reference voltage with a voltage corresponding to a maximum power point at a previous measurement point to extract the maximum power point for each measurement point.

In addition, the characteristic information of the renewable energy module may contain at least one of I-V sweeping information, current-voltage characteristic information, power-voltage characteristic information, and maximum power point extraction information for each measurement point.

Further, the fifth step may include synchronizing, by the control unit, the voltage and the current measured by the precise measurement unit according to a signal from a waveform generation unit for changing the resistance of the electrical load to track a maximum power point.

### EFFECTS OF THE INVENTION

According to the present invention, it is possible to increase reliability of real measurement data and calculate a result closest to a maximum power point by compensating for power loss caused by resistance of a cable constituting a system, internal resistance of a voltage sensor, and a measurement cable.

Further, according to the present invention, it is possible to realize performance verification through accurate maximum power estimation, by improving a measurement point cycle by providing an electrical load with a separate fixed DC power source for an increase of consumption of current provided by a renewable energy module according to a characteristic of the renewable energy module, which is a non-linear power source, and minimizing delay of a measurement point caused by residual current.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 shows a conventional performance verification apparatus for a solar cell;

FIG. 2 shows a configuration of a conventional power generation circuit for a solar cell for inducing a maximum output of the solar cell;

FIG. 3 shows a configuration of a performance verification apparatus for a renewable energy module according to the present invention;

FIGS. 4 and 5 show I-V sweeping of a performance verification apparatus for a renewable energy module according to the present invention;

FIG. 6 shows a graph of current-voltage characteristic information and power-voltage characteristic information of the performance verification apparatus for a renewable energy module according to the present invention.

FIG. 7 shows a graph for extraction of a maximum power point according to an increase or decrease of voltage based on a reference voltage in a performance verification apparatus for a renewable energy module according to the present invention;

FIG. 8 shows maximum power points collected over time in the performance verification apparatus for a renewable energy module according to the present invention; and

FIG. 9 shows a performance verification apparatus for a renewable energy module according to another embodiment of the present invention.

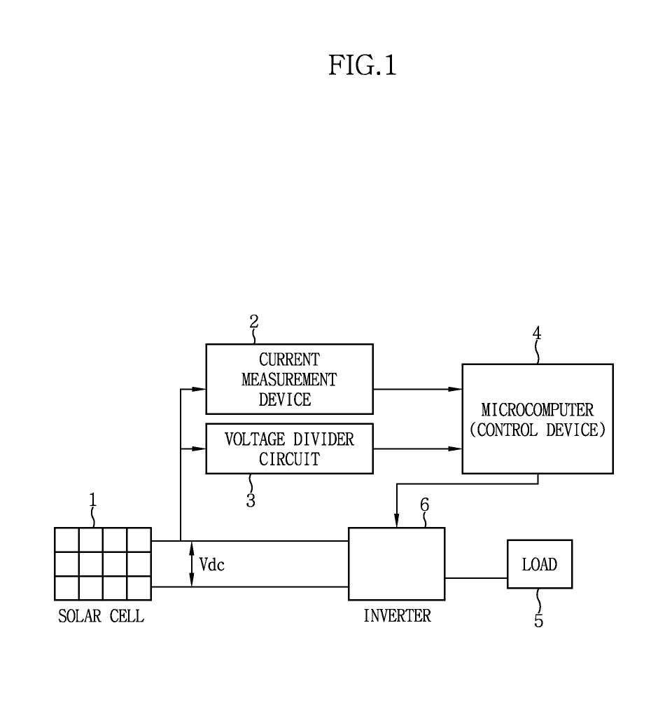

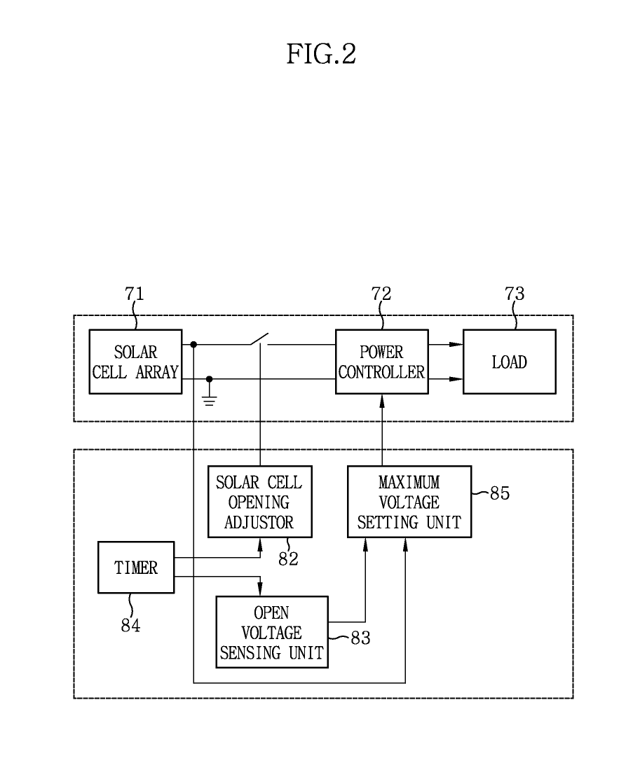

### DETAILED DESCRIPTION OF EXEMPLARY EMBODIMENTS

Exemplary embodiments of the present invention are disclosed herein. However, specific structural and functional details disclosed herein are merely representative for purposes of describing exemplary embodiments of the present invention, however, exemplary embodiments of the present invention may be embodied in many alternate forms and should not be construed as limited to exemplary embodiments of the present invention set forth herein. Like reference numerals in the drawings denote like elements.

Throughout this disclosure, when a part includes a component, it means that the part do not preclude the presence or addition of other components, but may include the other components, unless particularly mentioned otherwise.

The present invention provides an apparatus for realizing accurate estimation of a maximum power by compensating for power loss caused by cable resistance and contact resistance and causing synchronization points to accurately coincide with each other, in order to prevent reliability of an existing performance verification apparatus for a renewable energy module, such as a solar cell or an aerogenerator, from being degraded in verifying performance of the renewable energy module through maximum power point tracking by measuring power without consideration of power loss, which is caused by resistance of a cable and contact resistance between the cable and a connection terminal of an electrical load.

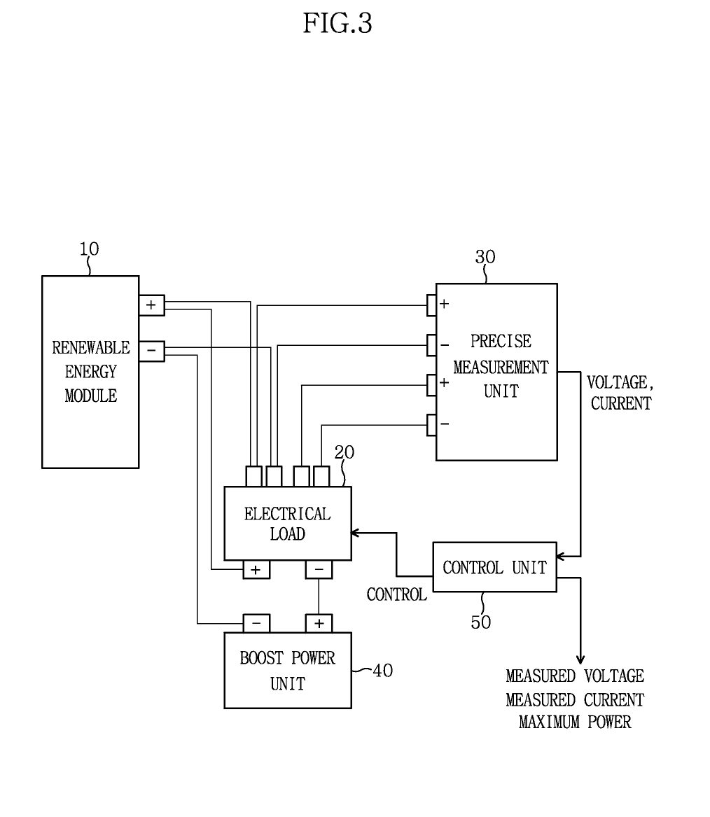

A configuration of the performance verification apparatus for a renewable energy module according to the present invention will be described in detail with reference to FIG. 3.

As shown in FIG. 3, the performance verification apparatus for a renewable energy module according to the present invention may include a renewable energy module 10, an electrical load 20, a precise measurement unit 30, a boost power unit 40 and a control unit 50.

The electrical load 20 includes a voltage sensor. An input terminal of the voltage sensor is connected to an output terminal of the renewable energy module 10 via a cable, such that the electrical load 20 is provided with power from the renewable energy module 10 to consume the power. A size of the load may be adjusted by external control.

Meanwhile, the boost power unit 40 may provide a previously set power to the electrical load 20 in consideration of a resistance value of the cable, which connects the electrical load 20 to the renewable energy module 10, in order to compensate for power loss caused by the cable.

Further, the precise measurement unit 30 has input terminals that are connected to the voltage sensor together with the output terminals of the renewable energy module 10 using a 4-wire method.

Such a 4-wire method is intended to precisely measure a resistance value of a fixed resistor. However, in the present invention, the 4-wire method is applied to obtain a value with no distortion caused by contact resistance or a cable connection for measurement and an additional cable connection for measurement in the precise measurement unit 30 in measuring a voltage value using a variable voltage sensor.

This is because a signal distortion caused by a measurement cable for sensing is not negligible, since the renewable energy module 10 is disposed in an outdoor area, while a measurement means for measurement is disposed in an environmentally stable indoor area.

The use of the 4-wired method enables the precise measurement unit 30 to precisely measure a real voltage with no distortion caused by contact resistance and internal resistance of a cable for voltage measurement.

No distortion of the measured voltage caused by the contact resistance and the internal resistance can increase the reliability of a measurement result and increase reliability and precision of maximum point tracking or characteristic measurement that is based on the measurement result.

In addition, the precise measurement unit 30 has an input terminal connected to a current output terminal of the electrical load 20 in order to measure current consumed by the electrical load 20 with high resolution.

It is possible to greatly increase measurement reliability by increasing the measurement precision for the voltage and the current in consideration of the cable resistance and the contact resistance as described above, compared to a case in which the voltage sensor embedded in the electrical load 20 is used in an existing performance verification apparatus for a renewable energy module.

Meanwhile, the control unit 50 may receive the measured current and voltage from the precise measurement unit 30, and monitors the characteristic while changing a resistance value of the electrical load.

In this process, the control unit 50 uses the voltage and the current measured by the precise measurement unit 30 at a point previously set according to the change of a resistance value of the electrical load 20, and synchronizes the change of the resistance value of the electrical load with the measurement point reflecting an effect of the change according to an appropriate reference to maintain the measurement reliability.

With such a configuration, it is possible to consider the cable resistance and the contact resistance, to easily prevent a maximum power point extraction error from being generated due to a difference between existing voltage and current points, and to greatly improve the precision.

Then, the control unit 50 can generate power based on the voltage and current measured by the precise measurement unit 30 and performs a tracking process based on maximum power point extraction, which will be described below.

In this case, the control unit 50 may extract and output a maximum power point to verify performance of the renewable energy module using a previously set Maximum Power Point Tracking (MPPT) algorithm.

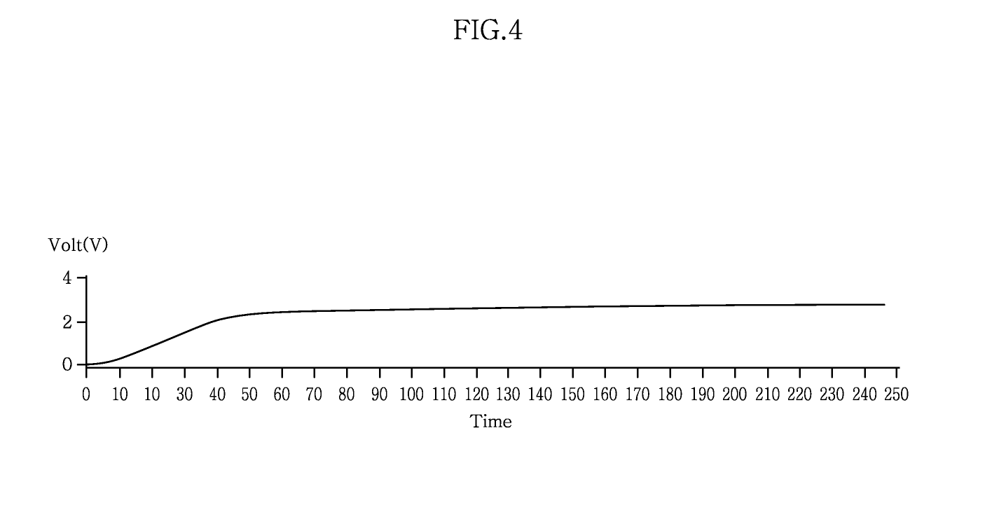

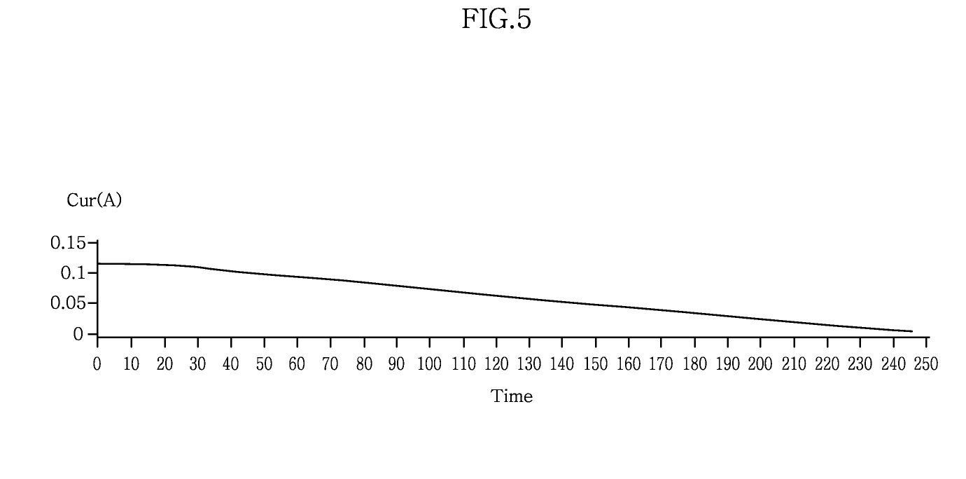

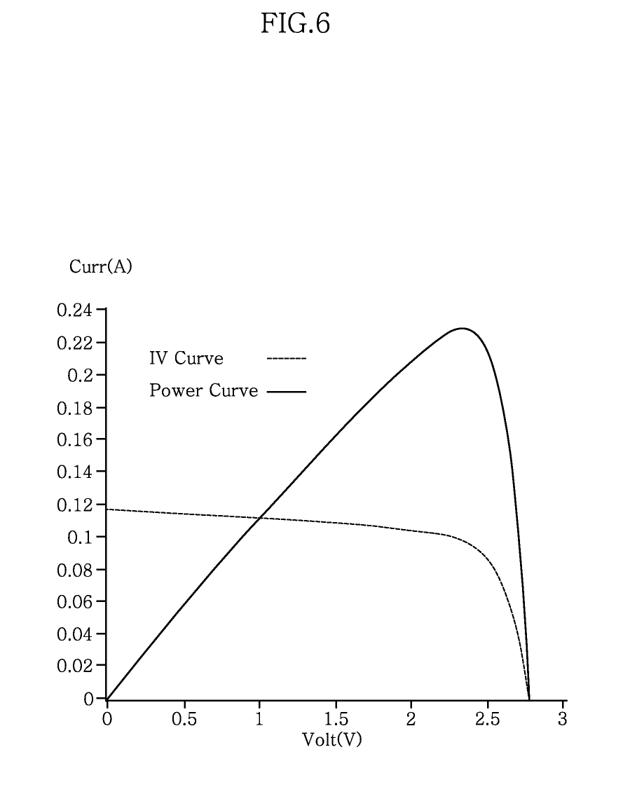

For this, as shown in FIGS. 4 and 5, the control unit 50 may continuously receive voltage and current from the precise measurement unit 30 while adjusting the electrical load 20, and may calculate current-voltage characteristic information of the renewable energy module 10 as shown in FIG. 6 through current-voltage sweeping (hereinafter, I-V sweeping).

Then, the control unit 50 may calculate the power-voltage characteristic information shown in FIG. 6 based on the current-voltage characteristic information, and may extract a maximum power point and a voltage at a maximum power point based on the power-voltage characteristic information and set the voltage as a reference voltage.

In this case, the control unit 50 may extract a reference current at the maximum power point and reference resistance of the electrical load 20 corresponding to the maximum power point, as well as the reference voltage.

The output power of the renewable energy module 10 is not maintained constant but continuously changed with a variation of a factor (sunlight, wind, electrolyte, etc.) to be converted into electricity. Accordingly, it is necessary to continuously optimize the electrical load 20 in order to realize consistent maximum output to find a maximum power generation amount.

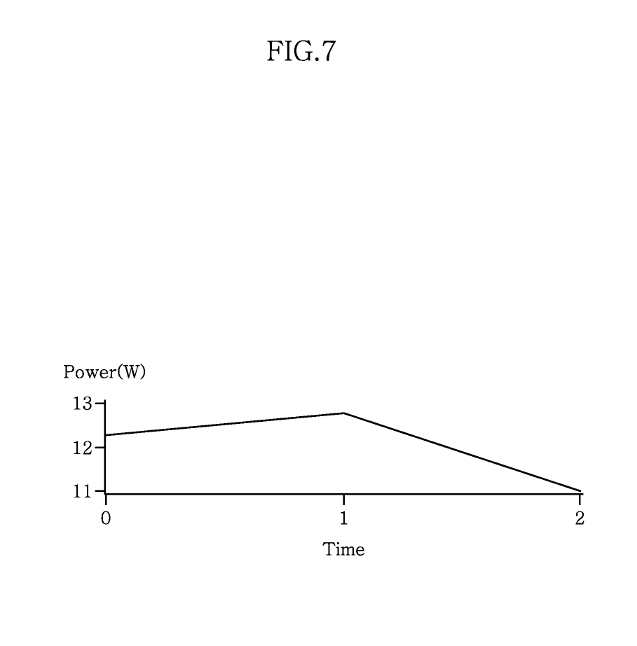

Accordingly, for maximum power point measurement after the reference voltage is set, the control unit 50 may increase or decrease the voltage based on the reference voltage as shown in FIG. 7 by adjusting the resistance value of the electrical load 20, compare a plurality of power values corresponding to the changed voltages, and select a maximum value as a next maximum power point.

In this case, for maximum power point measurement after the next maximum power point, the control unit 50 may sequentially measure the maximum power point by iteratively performing the process as described above by updating the reference voltage with a voltage corresponding to the next maximum power point and increasing or decreasing the voltage based on the updated voltage.

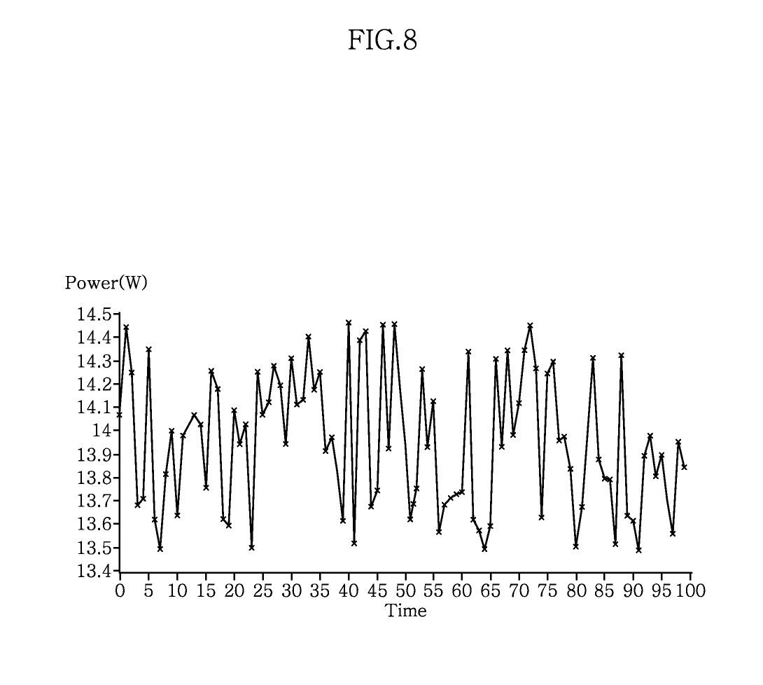

Accordingly, the control unit 50 extracts the maximum power point at each measurement point while increasing or decreasing the voltage based on the reference voltage, in which the control unit 50 may extract the maximum power point by updating the reference voltage with a voltage corresponding to a previous maximum power point at each measurement point. In this case, the control unit 50 may collect the maximum power points extracted at the respective measurement points, as shown in FIG. 8, and provide information on the collected maximum power points for the respective measurement points as characteristic information for efficiency of the renewable energy module 10.

In providing the characteristic information for efficiency of the renewable energy module 10, the control unit 50 may also provide I-V sweeping information, current-voltage characteristic information, power-voltage characteristic information and the like as the characteristic information of the renewable energy module 10, for example, for each measurement point or in a previously set period, as well as the maximum power point information for each measurement point.

This enables a user to easily judge performance of the renewable energy module using the characteristic information.

Meanwhile, the control unit 50 may instantaneously measure the maximum power point based on the current-voltage characteristic information through the I-V sweeping in addition to the above-described maximum power point measurement process, to thereby increase measurement speed.

In this case, when the maximum power point is measured only with the electrical load 20 in the maximum power point measurement process, a time is needed to reach the reference voltage for the maximum power point, which causes deviation of the synchronization point.

Accordingly, the boost power unit 40 is connected to the electrical load 20 in series as described above, provides a previously set fixed voltage to the electrical load 20, such that the current provided from the renewable energy module can be rapidly consumed by the electrical load 20, a time to reach the maximum power point and a measurement point cycle can be accelerated, and the measurement points can be easily synchronized.

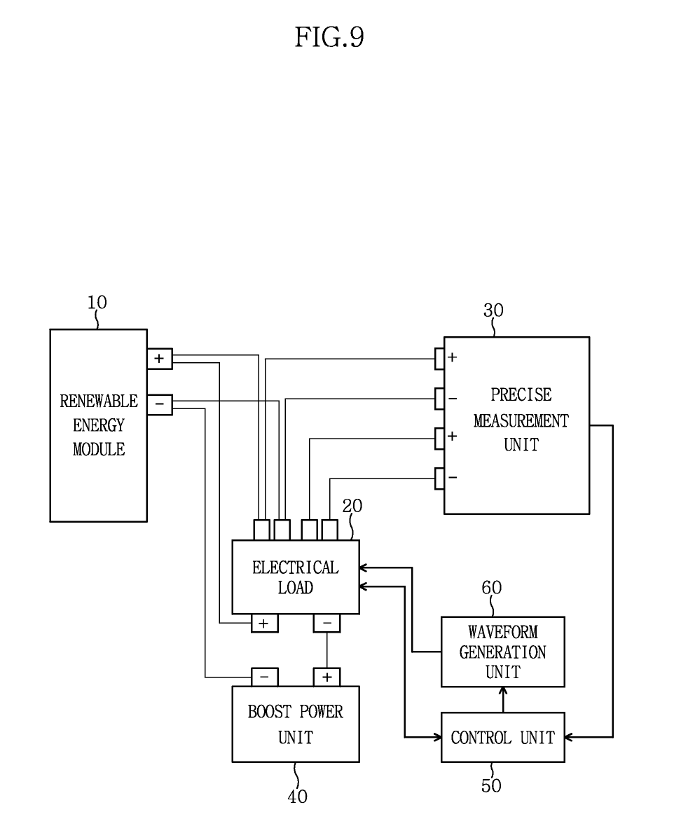

Meanwhile, the performance verification apparatus for a renewable energy module according to an embodiment of the present invention may include a waveform generation unit 60, in addition to the configuration of FIG. 3, as shown in FIG. 9.

This enables the control unit 50 to control the waveform generation unit 60 to provide a waveform for changing the resistance value of the electrical load 20 when a change of the electrical characteristic of the renewable energy module 10 must be rapidly verified. Thus, the control unit 50 can rapidly synchronize the voltage and the current received from the precise measurement unit according to the waveform, thereby shortening a measurement period of the maximum power point.

That is, the control unit 50 can rapidly perform the I-V sweeping by causing synchronization points to coincide with each other according to the waveform, thereby easily acquiring a maximum power point at each measurement point.

What is claimed is:

1. A performance verification apparatus for a renewable energy module, the apparatus comprising:
an electrical load that consumes power output from the renewable energy module through variation of internal resistance, the electrical load including a voltage sensor and a current measurement terminal;
a precise measurement unit for measuring a voltage with no distortion caused by contact resistance and internal resistance of a cable for voltage measurement and measuring current flowing through the electrical load, the precise measurement unit having an input terminal connected to an input terminal of the voltage sensor of the electrical load together with an output terminal of the renewable energy module using a 4-wire method;
a boost power unit for providing the electrical load with a compensation power previously set according to a loss power caused by a cable for connecting the input terminal of the voltage sensor to the output terminal of the renewable energy module; and
a control unit for receiving the measured voltage and current from the precise measurement unit to perform control of the electrical load and synchronization between the measured voltage and current, and tracking a maximum power point using a Maximum Power Point Tracking (MPPT) algorithm based on the synchronized measured voltage and current of the electrical load, wherein the control unit collects an I-V sweeping result of the renewable energy module as characteristic information by adjusting the electrical load during operation of the MPPT algorithm.

2. The performance verification apparatus according to claim 1, wherein the boost power unit provides a fixed DC voltage to the electrical load to accelerate power consumption of the electrical load.

3. The performance verification apparatus according to claim 1, wherein the control unit sets a voltage corresponding to the maximum power point as a reference voltage and extracts a power with a maximum value among a plurality of powers generated by increasing or decreasing a voltage based on the reference voltage, as a next maximum power point.

4. The performance verification apparatus according to claim 3, wherein the control unit updates the reference voltage with a voltage corresponding to the next maximum power point measured through the reference voltage, and updates the reference voltage with a voltage corresponding to a maximum power point at a previous measurement point to extract the maximum power point for each measurement point.

5. The performance verification apparatus according to claim 1, wherein the characteristic information contains at least one of I-V sweeping information, current-voltage characteristic information, power-voltage characteristic information, and maximum power point extraction information for each measurement point.

6. The performance verification apparatus according to claim 1, further comprising a waveform generation unit for providing a signal to change the resistance of the electrical load,
wherein the control unit synchronizes the voltage and the current measured by the precise measurement unit according to the signal from the waveform generation unit to track a maximum power point.

7. A performance verification method for a renewable energy module, the method comprising:
a first step of receiving, by an electrical load, voltage and current from the renewable energy module, the electrical load including a voltage sensor and a current measurement terminal;
a second step of providing, by a boost power unit, the electrical load with a compensation power previously set according to resistance of a cable for connecting the input terminal of the voltage sensor to an output terminal of the renewable energy module;
a third step of measuring, by a precise measurement unit, a voltage with no distortion caused by contact resistance and internal resistance of a cable and measuring current flowing through the electrical load, the precise measurement unit having an input terminal connected to an input terminal of the voltage sensor of the electrical load together with an output terminal of the renewable energy module using a 4-wire method; and
a fourth step of receiving, by a control unit, the measured voltage and current from the precise measurement unit to perform control of the electrical load and synchronization between the measured voltage and current, and tracking a maximum power point using a Maximum Power Point Tracking (MPPT) algorithm based on the synchronized measured voltage and current, wherein the control unit collects an I-V sweeping result of the renewable energy module as characteristic information by adjusting the electrical load during operation of the MPPT algorithm.

8. The performance verification method according to claim 7, further comprising a fifth step of setting, by the control unit, a voltage corresponding to the maximum power point as a reference voltage and extracting a power with a maximum value among a plurality of powers generated by increasing or decreasing a voltage based on the reference voltage, as a next maximum power point.

9. The performance verification method according to claim 8, wherein the fifth step comprises updating, by the control unit, the reference voltage with a voltage corresponding to the next maximum power point measured through the reference voltage, and updating the reference voltage with a voltage corresponding to a maximum power point at a previous measurement point to extract the maximum power point for each measurement point.

10. The performance verification method according to claim 7, wherein the characteristic information of the renewable energy module contains at least one of I-V sweeping information, current-voltage characteristic information, power-voltage characteristic information, and maximum power point extraction information for each measurement point.

11. The performance verification method according to claim 7, wherein the fifth step comprises synchronizing, by the control unit, the voltage and the current measured by the precise measurement unit according to a signal from a waveform generation unit for changing the resistance of the electrical load to track a maximum power point.
